(19) United States
(12) Patent Application Publication
(10) Pub. No.: US 2010/0055809 A1
(43) Pub. Date: Mar. 4, 2010

(54) PROCESS OF FABRICATING A WORKPIECE USING A TEST MASK

(75) Inventors: James M. Pak, Sunnyvale, CA (US); Mien Li, Sunnyvale, CA (US); Go Nagatani, Mountain View, CA (US); Yana Matsushita, Mountain View, CA (US); Julie Diane Segal, Palo Alto, CA (US)

Correspondence Address: LARSON NEWMAN & ABEL, LLP, 5914 W. COURTYARD DRIVE, SUITE 200, AUSTIN, TX, 78730, US

(73) Assignee: SPANSION LLC, Sunnyvale, CA (US)

(21) Appl. No.: 12/206,310

(22) Filed: Sep. 8, 2008

Related U.S. Application Data
(60) Provisional application No. 61/093,646, filed on Sep. 2, 2008.

(51) Int. Cl. H01L 21/66

(52) U.S. Cl. 438/17; 257/E21.531

(57) ABSTRACT

A product workpiece can be processed to form product dice. A test mask can allow intentional changes to be made to a feature on the product workpiece to examine how the altered feature performs. Use of the test mask may be used or not used based on the needs or desires of skilled artisans. By using the test mask, a separate dedicated test structure is not required to be formed in a scribe lane or within an area that could otherwise be used for a product die. Thus, the sampling level by using the test mask can be varied. Also, separate test workpieces, which may not be processed using a significantly different process flow or at significantly different times as compared to product workpieces, are not required. The product workpiece with the altered feature can be electrically tested without the need to form test or bond pads.

### BACKGROUND

1. Field of the Disclosure

This disclosure relates to processes of fabricating workpieces, and more particularly to, processes of fabricating workpieces using test masks.

2. Description of the Related Art

Dedicated test structures are extensively used on test workpieces (not sold for revenue) or on product workpieces (include product dice that can be sold for revenue) to gain information regarding the shape or performance of electrical components or other features. Test workpieces typically have process flows and masks that are different from process flows and masks used for product workpieces. A processing operation, which is used in production but believed to have no affect on dedicated test structures being formed, may be omitted from a process flow for the test workpieces. However, the omitted processing operation may have an actual significant impact on the process integration, and therefore, the test workpieces may not yield accurate information regarding a process integration issue. Also, the test workpieces may be processed as a lot separate from and at a significantly different time from another lot of product workpieces. The processing conditions within processing equipment can vary with time. For a particular piece of processing equipment, its characteristics can widely vary as a function of time (e.g., as time since the most recent maintenance increases). For example, polymer buildup within an etch chamber increases as the number of workpieces processed increases. The polymer buildup can affect electrical fields within the etch chamber which in turn can affect the etch characteristics. For deposition equipment, the particle counts can increase as the time since the last chamber clean increases.

Dedicated test structures can be fabricated using product workpieces to reflect more closely the processing conditions experienced by product dice. The dedicated test structure may reside in the scribe lines between product dice or occupy an area that would otherwise be used for a product die. With either option, there is no flexibility in changing the sample size (i.e., number of dedicated test structures) without changing the product masks, which can be expensive and risky, particularly for product masks having small feature sizes and requiring precise alignment.

Dedicated test structures in the scribe lines may provide insufficient or inaccurate information. The amount of data collected for any particular type of test structure may be limited by the size of the scribe lines and the number of other types of dedicated test structures, alignment marks, etc. Therefore, the amount of data may be too small to correctly isolate a cause of a problem. Also, the dedicated test structures in the scribe lines may not accurately reflect processing conditions near the center of an immediately adjacent product die. For example, a problem with etching densely populated features within the product die may not be detected by a dedicated test structure in the scribe lines because there may be insufficient area within the scribe lane to replicate the feature density near the center of the product die.

When dedicated test structures include areas of a product workpiece that could otherwise be used for product dice, use of such dedicated test structures can be costly. During the first few lots, valuable information may be obtained from the dedicated test structures; however, many lots later, the value of additional information can become much less and no longer justify the dedicated test structure. The dedicated test structures cannot be replaced by product dice until the entire mask set is replaced, which may not be for months or years later and will be very costly, both in the interim (less product dice produce) and when the new mask set is generated.

Without test structures, a problem that occurs on a product die may not be caught using an optical microscope inspection. A scanning electron microscope may be used, but a scanning electron microscope is slow when needing to inspect a large area of the workpiece in a quick manner. Some problems may be caught during electrical testing or wafer sort that is performed after fabrication of the product die is substantially completed and before the product die is assembled into a package for an integrated circuit. By the time the electrical test or wafer sort is performed, the entire product lot and potentially other product lots may have been processed through the operations that caused the problem. Thus, detection of the problem after product die fabrication is substantially complete with may be too late.

### BRIEF DESCRIPTION OF THE DRAWINGS

The present disclosure may be better understood, and its numerous features and advantages made apparent to those skilled in the art by referencing the accompanying drawings.

FIG. 1 includes an illustration of a top view of a product workpiece that includes regions corresponding to reticle fields.

FIG. 2 includes an illustration of a top view of one of the reticle fields of FIG. 1 that includes product dice corresponding to the reticle field.

FIG. 3 includes an illustration of a top view of a product die, as designed, wherein the product die includes a memory array, peripheral circuits, and bond pads.

FIG. 4 includes a schematic drawing that illustrates part of a set of product masks and one or more test masks can be used in conjunction with the product masks.

FIG. 5 includes an illustration of a cross-sectional view of portion of a product workpiece after forming a plurality of layers.

FIG. 6 includes an illustration of a top view of a mask used to pattern portions of layers of the workpiece of FIG. 5.

FIG. 7 includes an illustration of a top view of a different mask that includes an opening to further pattern selected portions of the layers of the workpiece of FIG. 5.

FIG. 8 includes an illustration of a top view of a reticle field of the workpiece, wherein some product dice are marked as converted test dice.

FIGS. 9 and 10 include illustrations of a top view and a cross-sectional view, respectively, of a portion of die after patterning a resist layer, hard mask layer, and a conductive layer, wherein word lines within a memory sector are severed.

FIG. 11 includes an illustration of a top view of a product die after patterning a resist layer, hard mask layer, and a conductive layer, wherein word lines within the memory sector are not severed.

FIGS. 12 and 13 include illustrations of top views of a converted test die and a product die, respectively, when exposed to a charged ambient.

FIGS. 14 and 15 include illustrations of cross-sectional views of workpieces with openings having high aspect ratios in accordance with other embodiments.

FIGS. 16 to 19 includes illustrations in which a workpiece includes an overhang that covers a defect.

FIGS. 20 to 23 includes illustrations of top views of workpieces in which a test mask can be used in conjunction with bit lines in accordance with a particular embodiment.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

A product workpiece can be fabricating in forming product dice. A test mask can allow intentional changes to be made to a feature on the product workpiece to examine how the altered feature performs. The test mask may be used or not used based on the needs or desires of skilled artisans. By using the test mask, a separate dedicated test structure is not required to be formed in a scribe lane or within an area that could otherwise be used for a product die. Thus, the sampling level by using the test mask can be varied without having to change any of the product masks. Also, separate test workpieces, which may be processed using a significantly different process flow or at significantly different times as compared to product workpieces, are not required. The product workpiece with the altered feature can be electrically tested without the need to form test or bond pads. In an embodiment, the electrical test may be performed to determine whether a conduction path exists between the adjacent conductive members based on exposing the conductive members to a charged ambient. As used herein, a conductive path includes not only an electrical short but also includes a leakage path, which has a conductance smaller than an electrical short but still allows a significant amount of current to flow between adjacent conductive features. The conductive lines may be word lines or bit lines within a memory array. In another embodiment, a voltage contrast inspection can be used.

As used herein, the term “converted test die” is intended to mean a die that is designed to be a product die that is later rendered non-functional by use of a test mask. A converted test die is not a dedicated test structure.

The term “dedicated test structure” is intended to mean a test structure that is not designed to be a functioning part of a product die under normal operating conditions of the product die, but is designed to provide information regarding a shape of a feature, electrical performance parameter, or other suitable test information. An example of a dedicated test structure includes an alignment mark, a contact chain, a transistor structure used for determining a threshold voltage, breakdown voltage, or the like, or another suitable structure measured, tested, or inspected during fabrication, electrical test, or wafer sort of a workpiece.

The term “product” or its variants, where referring to a lot, workpiece, or die is intended to mean that the lot, workpiece or die, as designed, that would include at least one functional die (e.g., passes electrical tests and wafer sort operations) that can sold for revenue. A product die may be altered by a test mask to make a portion of the product die non-functional or convert a product die into a converted test die.

The term “product mask” is intended to mean a mask that is part of a product mask set, and the term “test mask” is intended to mean a mask that is not part of a product mask set.

Attention is now directed to processes of fabricating a workpiece using a test mask. The information herein is provided to aid in understanding particular details, and is not to limit the present invention.

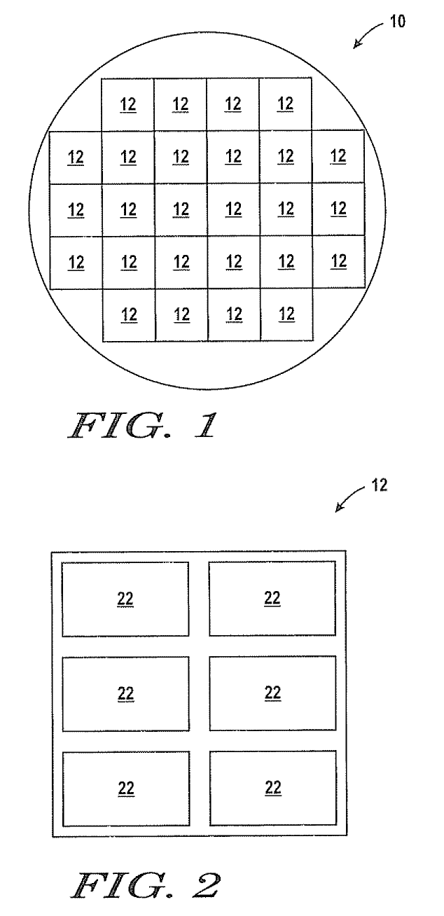

FIG. 1 includes a top view of a product workpiece 10 that includes product dice (not illustrated in FIG. 1) corresponding to reticle fields 12. The product workpiece 10 may be part of a product lot that includes 10, 25, 50, or a different number of product workpieces. In an embodiment, the product workpieces are substantially similar to one another. FIG. 2 includes a more detailed view of one of the reticle fields 12. The reticle field 12 includes product dice 22. The product dice 22 can be substantially identical to one another or may be different. The number of product dice 22 within the reticle field 12 can be more or fewer or have a different organization than illustrated in FIG. 2. The significance of the lot, workpieces, reticle fields, and dice will become more apparent later in this specification. Dedicated test structures used for alignment etc. may lie along the scribe lines between the product dice 22 but are not illustrated in FIG. 2.

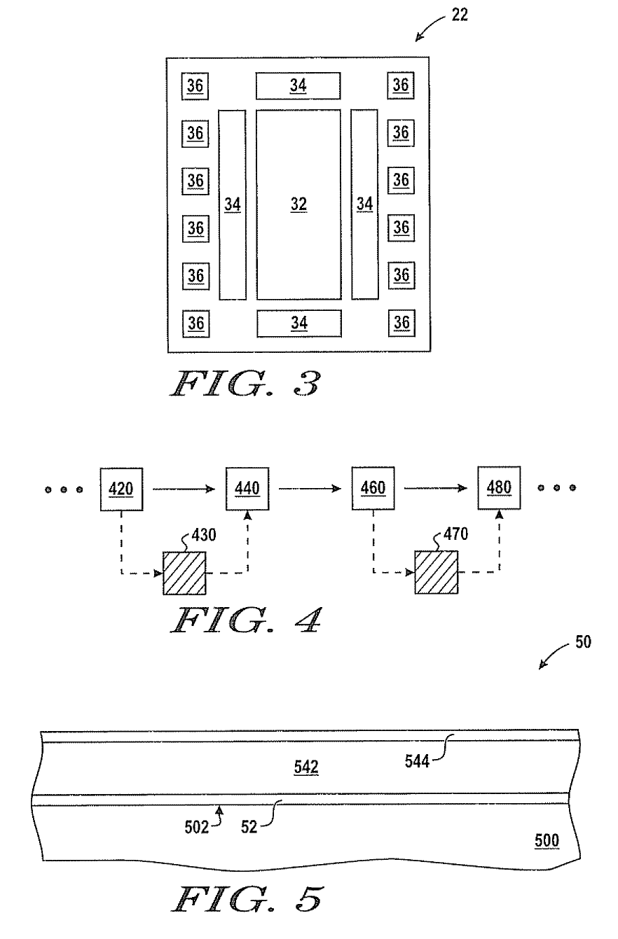

FIG. 3 includes an illustration of the product die 22, as designed. In one embodiment, the product die 22 is a standalone memory die. In another embodiment, the product die 22 can include a microprocessor, a microcontroller, a digital signal processor, a gate array, mixed signal circuits, or the like. As illustrated in FIG. 3, the product die 22 includes a memory array 32, peripheral circuits 34, and bond pads 36. The peripheral circuits 34 can include row or column decoders or strobes, sense amplifiers, another suitable circuit for a standalone memory die, or any combination thereof. Although not illustrated, interconnects connect the peripheral circuits 34 to portions of the memory array 32 and the bond pads 36. The circuits within the memory array 32 and peripheral circuits 34 are fabricated before the bond pads are formed.

In forming the product die 22, many different processing operations are used. The operations include annealing, film growth, film deposition, doping, masking, etching, polishing, other suitable operation, or any combination thereof. With respect to masking operations, in an embodiment, the product die 22 can be formed using 20 to 50 different masks. In another embodiment, the product die 22 can be formed using more or fewer masks. As will be explained in more detail, a test mask may be used on a product workpiece to provide information regarding process margin of process operations, determine limits of dimensions of features, or provide other useful information. A determination of whether or not to use a test mask can be made with short notice, and may be made significantly after a product lot has begun fabrication. The use of the test mask can be discontinued without having to alter product masks.

FIG. 4 includes an illustration that includes product masks 420, 440, 460, and 480. Each product mask can be a field isolation mask, a gate mask, a contact mask, an interconnect trench mask, a well implant mask, a source/drain mask, or other suitable mask. For simplicity, only four product masks are illustrated. The product masks 420, 440, 460, and 480 can be used sequentially or another product mask may be used between any pair of the product masks. Further, a product mask may have other sibling masks for different options. For example, the product mask 480 may be an interconnect trench mask for a standalone memory product with a x4 memory configuration, a different product mask (not illustrated) may be another interconnect trench mask for another standalone memory product with a x8 memory configuration that could be used instead of the product mask 480, and still another product mask may be still another interconnect trench mask for still another standalone memory product with a x16 memory configuration that could be used instead of the product mask 480. For any product die, only one of three interconnect trench masks would be used. All product workpieces will be processed using an appropriate set of product masks designed for a particular product die to be formed.

A product workpiece can be processed using a test mask. FIG. 4 includes test masks 430 and 470. None, only one, both, or more test masks can be used. The test masks can be used in conjunction with other processing operations to alter a portion of the product workpiece. The test mask may be used on all product workpieces or on part, but not all, product workpieces within a product lot (e.g., one product workpiece per product lot). The test mask may affect all product dice corresponding to a reticle field or less than all product dice corresponding to a reticle field (e.g., one, two or three product dice per reticle field). Within a product die, the test mask may affect substantially all of the product die or part, but not all, of the product die (e.g., a memory sector of a memory array, a set of registers within a central processing unit, another suitable part of the product die, or any combination thereof). In a particular embodiment, a test mask may be used and change a product die into a converted test die.

A test mask may be used or not used based on the needs or desires of skilled artisans. In an embodiment, one or more test masks can be used on all product dice of product workpieces when the product dice are being fabricated for the first time. Later, when prototyping, the number of test masks or the frequency of use may be reduced, such that only some product dice, but not all product dice, on one or two product workpieces per lot are affected. When the product dice are later produced in commercial volumes, the test mask may or may not be used on each lot of product workpieces. For example, the test mask may only be used if an unexplained decrease in yield occurs or if new processing equipment or a substantially maintenance or modification of processing equipment has occurred.

Although not required, the test mask may be used in conjunction with a product mask of a similar type. For example, if the product mask 420 is an implant mask, the test mask 430 may also be an implant mask, and if the product mask 460 is a gate mask, the test mask 470 may also be a gate-level mask. When product and test implant masks are used in conjunction with each other, the test mask can allow a region of the product die to have a different conductivity type, doping species, dose, or energy as compared to the same region on another product die that is processed using the product mask, but not processed using the test mask. When product and test gate masks are used in conjunction with each other, the test mask can allow a region of the product die to have narrower, wider, shorted or severed features as compared to the same region on another product die that is processed using the product mask, without the test mask.

In another embodiment, the test mask may be independent of other product masks and may be of a different type compared to the immediately preceding product mask.

After reading this specification, skilled artisans will appreciate the number and use of the test masks can be widely varied to meet the needs or desires for a particular application. The use of the test mask may be frequent (e.g., used on each product lot or on one lot per a predetermined number of lots), infrequent (e.g., used only as needed or desired), or discontinued altogether without affecting the product masks within the product mask set. Thus, product masks do not need to be changed whether or not test structures are used on an ad-hoc basis. Furthermore, any design revisions, in most cases, will not necessitate generation of a new test mask.

After the product workpiece is processed using the test mask, the product die can be tested at that time or at a later time. In an embodiment, the test mask can be used to affect conductive members, and a test can be performed without any bond or test pads being present within the product die. For example, the product die can be exposed to an electron beam, an ion beam, or another charged ambient, and the affected die can be inspected for potential electrical shorts or opens. In a particular embodiment as described later in Example 1, word lines can be severed and subjected to a voltage contrast inspection to determine if there are any undesired electrical shorts between adjacent word lines. The undesired electrical shorts may not be visible using an optical microscope. In another particular embodiment, different portions of an active region that are designed to be electrically isolated from one another can be electrically shorted by doping using an implant mask. The affected die can be subjected to a voltage contrast inspection to determine if there are any undesired electrical opens between different portions of the active region. In these particular embodiments, the product workpieces can be further processed using the remainder of the product masks.

The inspections can be performed without having to form bond or test pads on the product die and contacting the product die with probes, which can be a source of contamination. Useful electrical information can be obtained without having to process the product workpieces through post-fabrication electrical test or wafer sort. The test and sort operations are performed late in the process and can be performed well after fabrication problems or other issues would have occurred. For example, the sort operation may be the first time undesired conduction paths (e.g., electrical shorts or leakage paths) may be detected. For example, two immediately adjacent word lines or bit lines may have an undesired conduction path. By the time the sort operation is performed, it is too late to perform any remedial action on the product workpiece or other workpieces within the same product lot. Still further, other product lots may have been processed through the process operation where the problem originated by the time the first product lot with the problem is detected at the sort operation. Using the test mask in accordance with the processes described herein, an electrical test can be performed earlier in the fabrication process to detect an undesired conductive path and potentially perform remedial action or address the cause of the problem before subsequent product lots or even other workpieces within the same product lot are processed.

After reading this specification, skilled artisans will appreciate that the process flow can be diverted at-will or intentionally to introduce a controlled variation of an affected product die at nearly any time, even with short notice. All other process operations and equipment can be used without any other change. The level of sampling used is variable. Sampling can be performed the product lot level, the workpiece level, the product die level, or even a smaller level (e.g., at a sector level within a memory array).

The process can be used and have a relatively small impact on production. If the test mask only affects a few product dice within a reticle field, the other product dice can still be operational and sold for revenue. Even within the few product dice, the test mask may affect only a small portion of the product dice, and one or more of those few product dice may still be operational and sold for revenue. In a particular embodiment, a product die may be a standalone memory with several memory sectors. The product die may have a few extra memory sectors for redundancy purposes. If the test mask and processing renders one of the memory sectors non-functional, the other memory sectors may not be affected. Thus, with redundancy, the non-functional memory sector is not used, and the product die has enough other functional memory sectors that the product die can still be sold for revenue as a functional standalone memory.

The concepts described herein provide a good balance between the need for data (using the test mask) and ability to produce product dice for revenue. As the need for data decreases, the test mask can be used on fewer product workpieces, and therefore allow for higher yield. On the other hand, if the yield decreases for no apparent reason, use of the test mask can be increased to obtain more data that can help provide information quicker in determining a cause of, the extent of, or other information regarding the problem.

In an embodiment, the process can be used to introduce one variable at a time in the form of intentional defects. Because the test mask can be used on product workpieces, the product workpieces, including those with or without the intentional defects, can be otherwise processed using substantially the same process operations and equipment. In this manner, differences due to a different process flow or equipment, as used for short-loop test wafers, can be eliminated.

Although not required, the test mask can be designed so that test features on the product workpieces are formed much larger than the smallest dimension specified by the design rules for the product die. In an embodiment, the test features can have a smallest dimension that is at least approximately 5 times, 10 times, or 20 times larger than the smallest dimension specified by the design rules. In a particular embodiment, the test features may have a smallest printed dimension of approximately 1000 or 2000 nm, and the smallest dimension specified by the design rules (e.g., smallest dimension of the design rules) are less than approximately 100 nm or 65 nm. Therefore, the cost of fabricating the test mask can be relatively low (compared to a field isolation, gate, or contact mask), and alignment tolerance when using the test mask can be good (a non-critical alignment).

When testing the product workpiece using an electron beam, ion beam, or another charged ambient, an electrical test can be performed as an in-line test. In addition, the electrical test can more accurately detect problems that are not visible using an optical microscope. The electrical test can be performed without requiring pads or probes. Thus, the electrical test can be performed in real time or near real time without having to wait until the end of the process before valuable information is obtained. In this manner, defects can be detected or experimental feedback may be obtained more quickly.

The concepts described herein have advantages over dedicated test structures. The dedicated test structures can require many layers and masks that are specifically designed for a test. Thus, significant design and development time may be needed. When the dedicated test structures are formed on test workpieces, those test workpieces may not experience or be processed using the same conditions or equipment as compared to the product workpieces. Therefore, many variables may be introduced and make it harder to take information collected from test workpieces and extrapolate that information to product workpieces. When dedicated test structures are used on product workpieces, the dedicated test structure may reside in the scribe lines between product dice or occupy an area that would otherwise be used for a product die. With either option, there is no flexibility in changing the sample size without changing the product masks, which can be expensive and risky, particularly for product masks having small feature sizes and requiring a precise alignment. Dedicated test structures in the scribe lines may provide insufficient or inaccurate information (may not detect problems with isolated versus dense feature regions). When dedicated test structures occupy areas that could otherwise be used for product dice, use of such dedicated test structures can be costly. The dedicated test structures cannot be removed and replaced by product dice until the entire mask set is replaced, which may not be for months or years later and will be very costly.

The processing and tests are much faster and may be more accurate than analyzing using a scanning electron microscope (“SEM”). A SEM analysis can be very slow when millions of structures need to be inspected. Further, an electrical test is more accurate than a SEM analysis. A SEM analysis may determine that a residual portion does not fully extend between two adjacent conductive lines, and therefore, is not an electrical short. However, the testing as described herein will also detect leakage paths, which are not electrical shorts but still provide significant current flow between adjacent conductors. Thus, although the SEM analysis can detect the presence of residual portions, it may not correctly predict whether or not a conduction path exists between adjacent conductive lines.

### EXAMPLES

The following specific examples are meant to illustrate particular embodiments and not to limit the scope of the invention. While many details are provided with respect to materials, thicknesses, and formation techniques, such details are merely illustrative.

### Example 1

Example 1 demonstrates how the concepts as described above can be used with respect to forming and testing conductive lines, such as word lines within a memory sector, without any need of bond or test pads on the product die. While many details are provided with respect to materials, thicknesses, and formation techniques, such details are merely illustrative and not meant to limit the scope of the present invention.

Attention is now directed to a process of fabricating a product workpiece. FIG. 5 includes an illustration of a cross-sectional view of a portion of a product workpiece 50 that includes a substrate 500 and layers formed thereon. The portion of the product workpiece 50, as illustrated in FIG. 5, includes part of a partially fabricated product die. The substrate 500 can include a monocrystalline semiconductor wafer, a semiconductor-on-insulator wafer, a flat panel display (e.g., a silicon layer over a glass plate), or other substrate used to form electronic devices. The substrate 500 has a primary surface 502 from which electronic components can be formed over or within.

A dielectric layer 52, a conductive layer 542, and a hard mask layer 544 are formed over the substrate 500. The dielectric layer 52 can be a gate or capacitor dielectric layer and include an oxide, a nitride, an oxynitride, or any combination thereof, and have a thickness in a range of approximately 2 nm to approximately 30 nm. The conductive layer 542 can be a capacitor, gate, or other electrode or local interconnect layer and include a conductive material or a material that can be made conductive. In a particular embodiment, the conductive layer 542 can include amorphous silicon, polysilicon, a metal-containing compound, or any combination thereof. The conductive layer 542 may include a plurality of films having different compositions. The conductive layer can have a thickness in a range of approximately 20 nm to approximately 200 nm. The hard mask layer 544 can include an oxide, a nitride, an oxynitride or any combination thereof, and have a thickness in a range of approximately 2 nm to approximately 50 nm. In a particular embodiment, the hard mask layer 544 can also be an antireflective layer, or a separate antireflective layer can be used in place of or in conjunction with the hard mask layer 544. Each of the dielectric layer 52, the conductive layer 542, and the hard mask layer 544 can be formed using a conventional or proprietary growth or deposition technique.

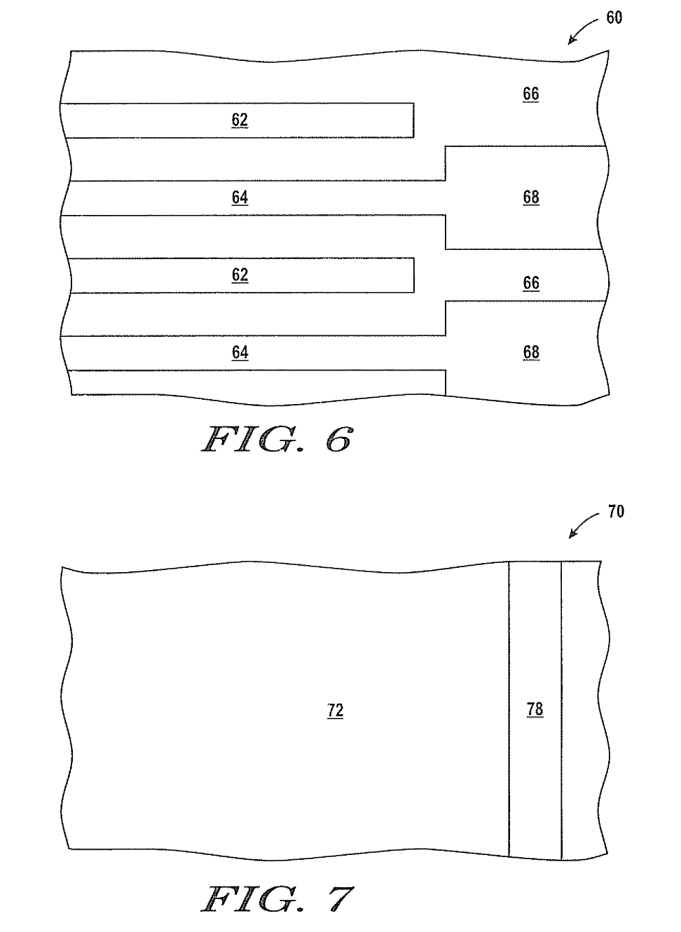

Masks illustrated in FIGS. 6 and 7 are described before addressing the processing used in conjunction with the masks. FIG. 6 includes an illustration of a portion of a product mask 60 that can be used to pattern the conductive layer 542 into conductive members, such as word lines. The product mask 60 may be referred to as a gate mask or a word line mask. The product mask 60 can be used to pattern a positive acting resist material and includes features 62 and 64 and transparent areas 66. In another embodiment, the features 62 and 64 can be transparent and the areas 66 can be opaque when a negative active resist material is to be patterned. In a particular embodiment, the features 62 correspond to odd-numbered word lines, and the features 64 correspond to even-numbered word lines. In an embodiment, the widths of resist features that correspond to the features 62 and 64 are no greater than approximately 200 nm, and in another embodiment are less than approximately 90 nm. In a particular embodiment, the widths of the resist features are within approximately 5 nm of the smallest dimension allowed by the design rules (e.g., 65 nm). The widths of the flared portions 68 can be significantly wider than the widths of the features 62 and 64 within a memory sector.

The portion of the product mask 60 patterns a portion of a memory sector near the right-hand edge of a sector. The features 64 include flared portions 68 that are coupled to row decoders, strobes, or other circuitry (not illustrated) further to the right of the portion illustrated in FIG. 6. At the left-hand side of the memory sector (not illustrated), the features 62 have flared portions, similar to flared portions 68, and the features 64 terminate before the flared portions. The product mask 60 will be used for all product workpieces in the lot.

FIG. 7 includes an illustration of a portion of a test mask 70 that can be used to pattern the conductive layer 542 to allow some of the word lines to electrically float during a subsequent test. The test mask 70 can be used to pattern a positive acting resist material and includes a feature 72 and a transparent area 78. In another embodiment, the feature 72 can be transparent and the area 78 can be opaque when a negative active resist material is to be patterned. In a particular embodiment, the area 78 can be used to pattern the flared portions 68 created by the product mask 60. In a particular embodiment, only the even numbered word lines are affected, not the odd numbered word lines. A corresponding opening within a resist layer (produced by the area 78) can have a width that is at least approximately 5 times wider than the widths of the features 62 and 64 within the memory sector. In one embodiment, the width is greater than approximately 0.5 microns, greater than approximately 1.1 microns, greater than approximately 2 microns, or even larger. Thus, a non-critical alignment may be used with the test mask 70. In a particular embodiment, registration marks outside the reticle field can be used for alignment. Use of alignment marks within a reticle field is not required, but the alignment marks can be used if desired.

The use of the test mask 70 can be made at nearly any time before a subsequent insulating layer is formed over the patterned word lines. The test mask 70 may be used on all product lots, some product lots, all product dice, some product dice, etc. The test mask 70 can render a memory sector non-functional. Depending on the level of redundancy, the product die altered when using the test mask 70 may or may not become a converted test die. In one embodiment, the test mask 70 is used on one or a few product workpieces within a product lot. A majority of the product workpieces within the product lot will not be processed using the test mask 70.

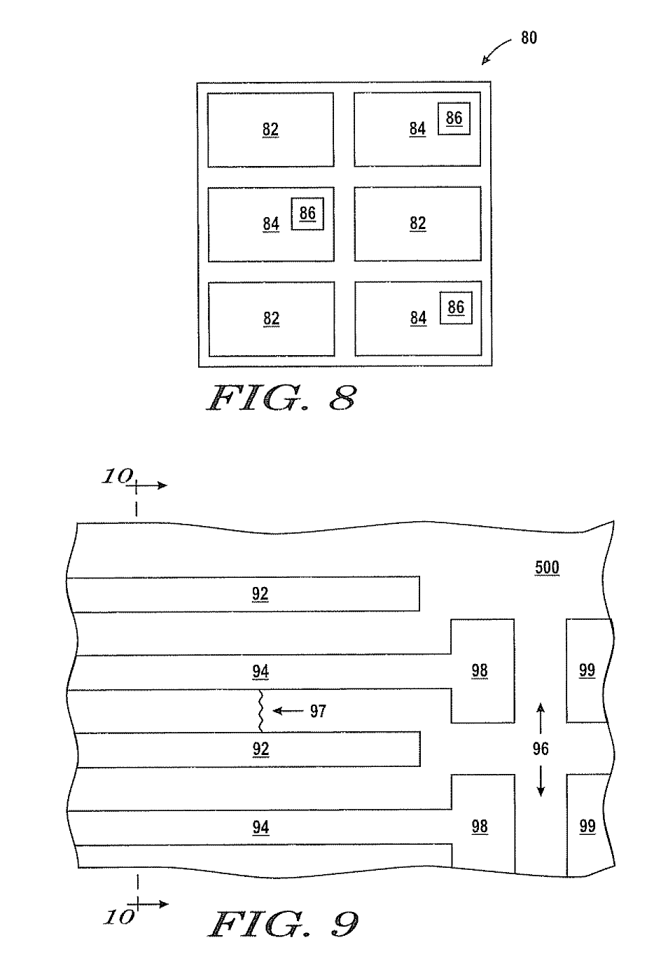

FIG. 8 includes an illustration of a top view of product dice 82 and 84 corresponding to the reticle field 80. The masks 60 and 70 are used when patterning the product dice 82 and 84. In one particular embodiment, product dice 82 remain product dice after using the test mask 70, and the even numbered word lines will not be severed or otherwise disconnected from a row decoder or strobe circuit. The product dice 84 may become converted test dice, as portions of the word lines corresponding to features 64 of the mask 60 will not be electrically connected to row decoders or strobes and will be allowed to electrically float. To assist a subsequent sort operation, a marker 86 will be printed as a corresponding feature (not illustrated) in the test mask 70. At wafer sort, the sort system will detect the marker 86 and will not perform a sort operation on the dice 84. The product dice 82 will be sorted because a marker 86 is not present on these product dice.

In another embodiment, the product dice 84 are still affected by the test mask 70, but due to redundancy, the product dice 84 may still be functional, although a memory sector has been rendered non-functional. Because the product dice 84 may be sorted, the marker 86 may or may not be used.

Referring to FIG. 5, a resist layer is formed over the product workpieces and patterned, and the hard mask layer 544, the conductive layer 542 are patterned. Different process sequences can be used. In one embodiment, all product workpieces within the lot are exposed using the product mask 60. One or a few workpieces within the product lot will be exposed using the test mask 70, but the remaining product workpieces within the product lot will not be exposed to the mask 70. The resist layer is developed, and the hard mask layer 544 and the conductive layer 542 can then be etched. In another embodiment, the order for the exposures to the masks 60 and 70 can be reversed. In still another embodiment, the resist layer can be developed for a first time after exposing using either mask, and the resist layer can be developed for a second time after exposing using the other mask. In a further embodiment, a first resist layer can be exposed using one of the masks and developed, followed by an etch. The first resist layer can then be removed, and a second resist layer can be exposed using the other mask and developed, followed by an etch. After reading this specification, skilled artisans will appreciate the flexibility in forming and patterning resist layer(s) and etching.

In one exemplary, non-limiting embodiment, a resist layer is formed over the hard mask layer 544 for all of the product workpieces within the product lot. The resist layer for all workpieces is selectively exposed to radiation using the product mask 60. For one or only a few product workpieces within the product lot, the resist layer is selectively exposed to radiation using the test mask 70. All product workpieces can then be developed to form a patterned resist layer. Post-develop processing can be performed if needed or desired (e.g., hard baking the patterned resist layer, exposing the patterned resist layer to ultraviolet radiation, or the like). The hard mask layer 544 can be patterned and the resist layer can be removed using conventional or proprietary etching and removal techniques.

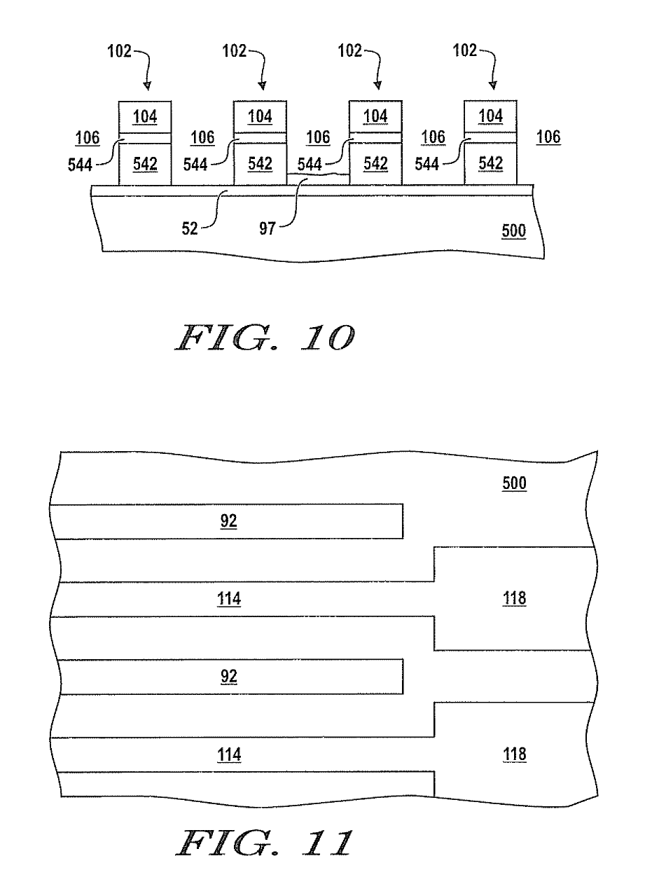

The conductive layer 542 is selectively etched to form the patterns as illustrated in FIGS. 9 to 11. FIGS. 9 and 11 include top views to illustrate positional relationships between different parts of the product die, and FIG. 10 includes a cross-sectional view at sectioning line 10-10 in FIG. 9. Insulating layers, including the dielectric layer 52, are not illustrated in FIGS. 9 and 11 to simplify understanding of features within the portions of the workpieces illustrated.

FIG. 9 includes a top view of a portion of a product die with the word lines within a memory sector severed. The product die may or may not become a converted test die depending on the number of memory sectors affected. The product die in FIG. 9 includes word lines 92 and 94. The word lines 94 include flared portions 98. Gaps 96 lie between the flared portions 98 and other flared portions 99. The other flared portions 99 are coupled to the row decoders or strobes or other circuitry, whereas the flared portions 98 are not connected to another part of the die. The word lines 94 are not electrically coupled to the row decoders or strobes or other circuitry, and thus, electrically float. Word lines 92 are coupled to row decoders or strobes or other circuitry and are described in more detail later with respect to FIG. 11. If the word lines 94 would not have been severed, the word lines 94 would not electrically float but would be coupled to other row decoders, strobes, or circuitry, similar to word lines 92.

As can be seen in FIG. 10, the openings between the portions of a patterned resist layer 104, the hard mask layer 544, and the conductive layer 542 can be relatively narrow and deep. An aspect ratio of an opening is a ratio of a depth of the opening to a width of the same opening. The openings between remaining portions of the layers 104, 542, and 544 can have aspect ratios at least approximately 2:1, at least approximately 5:1, at least approximately 9:1, or even larger. As the aspect ratio increases, the etching becomes more difficult. In a particular embodiment, a defect 97 lies between two of the word lines 92 and 94 in FIG. 9 and along a bottom of an opening between remaining portions of the conductive layer 542 in FIG. 10. The defect 97 can be resistive or conductive and may form a leakage path or an electrical short between the word lines 92 and 94. Although the defect 97 as illustrated in FIGS. 9 and 10, in practice, the defect 97 may be difficult or potentially impossible to see using an optical microscope.

FIG. 11 includes a top view of a portion of a product die that was not processed using the test mask 70. The product die includes word lines 92 and 114. The word lines 114 include flared portions 118. Unlike the die illustrated in FIG. 9, there is no gap formed (see gaps 96 in FIG. 9). Therefore, unlike the word lines 94, the word lines 114 are coupled to the row decoders or strobes or other circuitry. Word lines 92 are nearly mirror images of the word lines 114. Although not illustrated, the word lines 92 have flared portions similar to the flared portions 118 of the word lines 114. The word lines 92, for both dice, are coupled to row decoders or strobes or other circuitry.

Doped regions (not illustrated), such as source/drain regions, can be formed within the substrate 500 to form transistor structures include the doped regions, portions of the substrate 500, such as channel regions that lie between the doped regions and underlie the word lines 92, 94, and 114. Thus, from a top view, conductive members, formed from patterning the conductive layer 542, correspond to substantially the same shape as the word lines 92, 94, and 114 in FIGS. 9 and 11. The remaining portions of the resist layer 104 and the hard mask layer 544 can then be removed using a conventional or proprietary removal technique.

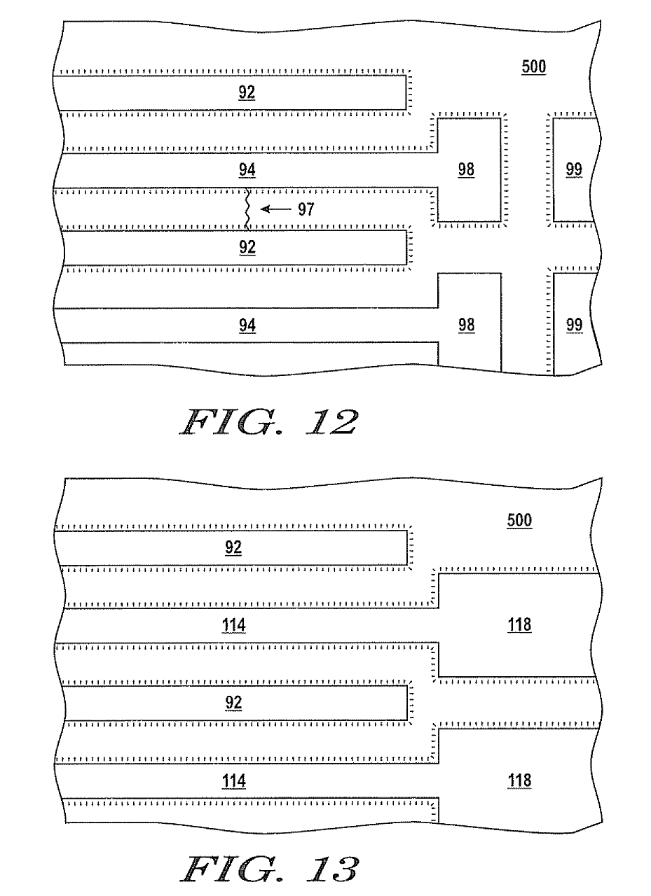

In order to detect the potential conduction path, a test can be performed on the product workpieces that include the dice processed using the test mask 70. After forming the word lines 92, 94, and 114, the workpiece can be exposed to a charged ambient to determine if a conduction path exists between a pair of immediately adjacent word lines. In one embodiment, a voltage contrast inspection can be performed. During a voltage contrast inspection, an electron beam can be directed to a portion of a workpiece that is to be inspected. FIGS. 12 and 13 include illustrations that represent images generated during a voltage contrast inspection that is performed using conventional or proprietary conditions.

FIG. 12 corresponds to a die in which an undesired conduction path between a pair of immediately adjacent word lines is present. The word lines 92 can be electrically connected to a doped region within the substrate or to a fixed potential (e.g., grounded). Therefore, electrons or other charged particles can migrate from the word lines 92 to another portion of the workpiece. The word lines 94, including flared portions 98, are designed to electrically float. Therefore, electrons or other charged particles are not designed to migrate from the word lines 94 to another portion of the workpiece. The flared portions 99 can be electrically connected to a doped region within the substrate or to a fixed potential (e.g., grounded), although the flared portions 99 do not need to be inspected or considered during the test.

If no conduction paths exist between pairs of word lines, the word lines 92 will be illuminated, but the word lines 94 will not be illuminated because they are to electrically float. Therefore, every other word line within the memory sector will be illuminated if no conduction paths between word lines 92 and 94 exist. If a conduction path exists between any of the word lines 92 and 94, the word line 94 having a conduction path to one or more word lines 92 will be illuminated. Referring to FIG. 12, the word line 94 near the center of the figure includes a conduction path to an adjacent word line 92 via the defect 97, regardless whether or not the defect 97 can be detected using an optical method. Therefore, the word line 94 near the center is illuminated because of the conductive path. The word line 94 closer to the bottom of FIG. 12 is electrically floating and does not have a conduction path to an adjacent word line 92. Therefore, the word line 94 near the bottom is not illuminated during the test. Locations of the defects that are too small or are buried can therefore be easily detected by looking for entire lines lightening up (when should be dark) or not lightening up (when should be bright) in an alternating fashion

FIG. 13 corresponds to a product die that was not processed using the test mask 70. The word lines 92 and 114 can be electrically connected to a doped region within the substrate or to a fixed potential (e.g., grounded). Therefore, electrons or other charged species can migrate from the word lines 92 and 114 to another portion of the workpiece. During a voltage contrast inspection, the word lines 92 and 114 are illuminated, regardless of whether a conduction path does or does not exist.

If an undesired conductive path is found on a die processed using the test mask 70, further analysis or processing can be performed. For example, failure analysis can be performed to analyze the product workpiece in more detail and determine a cause of the undesired conduction path. In another embodiment, the product workpiece may be processed through a megasonic clean to remove any particles that are lying along exposed surfaces of the workpiece. In still another embodiment, a relatively short isotropic etch may be performed if any conductive members would remain unetched between the word lines 92 and 94. In a further embodiment, another suitable analysis or remedial action may be performed. After the workpiece with dice is processed, a decision can be made whether an additional workpiece should be processed with the test mask 70 and tested or whether the remainder of the product lot is to be processed without any further testing.

In an alternative embodiment, a different charged species can be used. Instead of using an electron beam, an ion beam may be used. The ion beam can be a relatively light atom that does not significantly etch or change doping levels within the workpiece. For example, the charged ambient can include helium ions, neon ions, or any combination thereof. Because helium and neon are relatively light, no significant etching of exposed surfaces would occur. Also, if helium or neon would be implanted into the substrate, they would not significantly affect the electrical characteristics of the product die.

Although not illustrated, the product workpieces can be further processed to form additional insulating layers and to form one or more levels of interconnects. The last interconnect level typically includes bond pads. A passivation layer is formed over workpiece including the bond pads, and bond pad openings can be formed that extend through the passivation layer to the bond pads. Underbump metallization and conductive bumps may or may not be formed within the openings in the passivation layer. For the purposes of this specification, underbump metallization and conductive bumps are not considered to be bond pads.

The product workpieces can be placed into a sorting system, and a sort operation can be performed. The sorting system may have a module that detects the presence or absence of the marker 86 (see FIG. 8). If the marker 86 is detected, the sort operation may not performed on that particular product die. If the marker 86 is not detected, the sort operation is performed on that particular product die because it is a product die. Thus, the marker 86 can be used to bypass sorting dice that are expected to fail a test performed at sort. Therefore, the sorting operation can be performed more quickly.

Thus, the concepts described herein can be used to test a portion of a product workpiece during process development or as a process monitor.

### Example 2

Example 2 demonstrates how the concepts as described herein can be extended to other stacks that define openings having aspect ratios that are even larger than the embodiments as described with respect to Example 1.

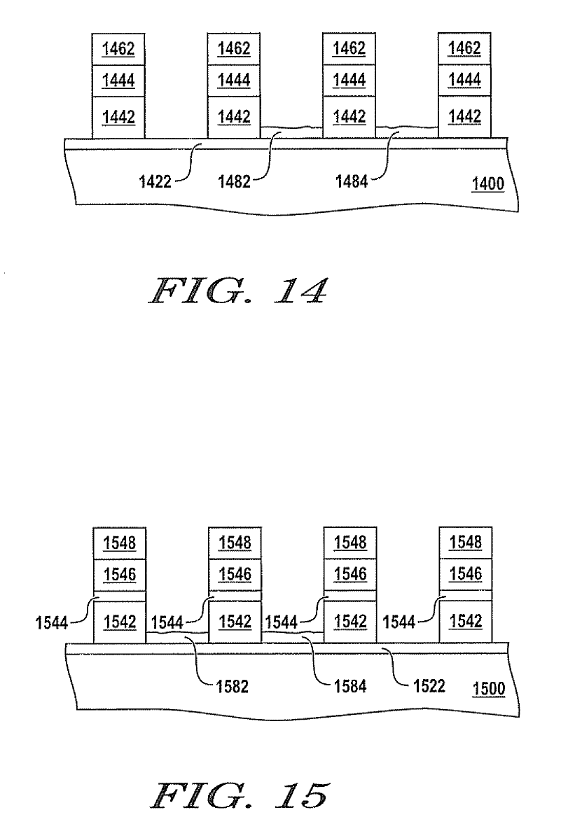

FIG. 14 includes an illustration of a portion of a workpiece that includes a substrate 1400, a dielectric layer 1422, a patterned conductive layer 1442, another patterned conductive layer 1444, and a mask layer 1462. Such a structure may be formed as part of an integrated circuit having different work functions for n-channel and p-channel transistors. For example, the patterned conductive layer 1442 may be designed to achieve a particular work function, and the other patterned conductive layer 1444 may be a conductive strapping layer, such as doped polysilicon. With more layers, the openings between the features as illustrated in FIG. 14 are deeper, and thus, the aspect ratio of the openings is larger. Defects 1482 and 1484 lie along the bottoms of the openings and may not be visible with an optical microscope.

FIG. 15 includes an illustration of a portion of a workpiece that includes a substrate 1500, a dielectric layer 1522, a patterned charge storage layer 1542, a patterned insulating layer 1544, a patterned control gate electrode layer 1546, and a mask layer 1548. Such a structure may be formed as part of an integrated circuit having nonvolatile memory cells. Similar to the structures in FIG. 14, with more layers, the openings between the features as illustrated in FIG. 15 are deeper, and thus, the aspect ratios of the openings are larger. Defects 1582 and 1584 lie along the bottoms of the openings and may not be visible with an optical microscope.

In another embodiment, a defect does not have to lie along a bottom of an opening. For example, a defect may lie between portions of a layer spaced apart from the bottom of an opening, such as the patterned conductive layer 1444 or the patterned control gate electrode layer 1546.

### Example 3

Example 3 demonstrates how the concepts as described herein can be extended to surface topologies that may hide a defect, such it may not be seen from a top view of a workpiece.

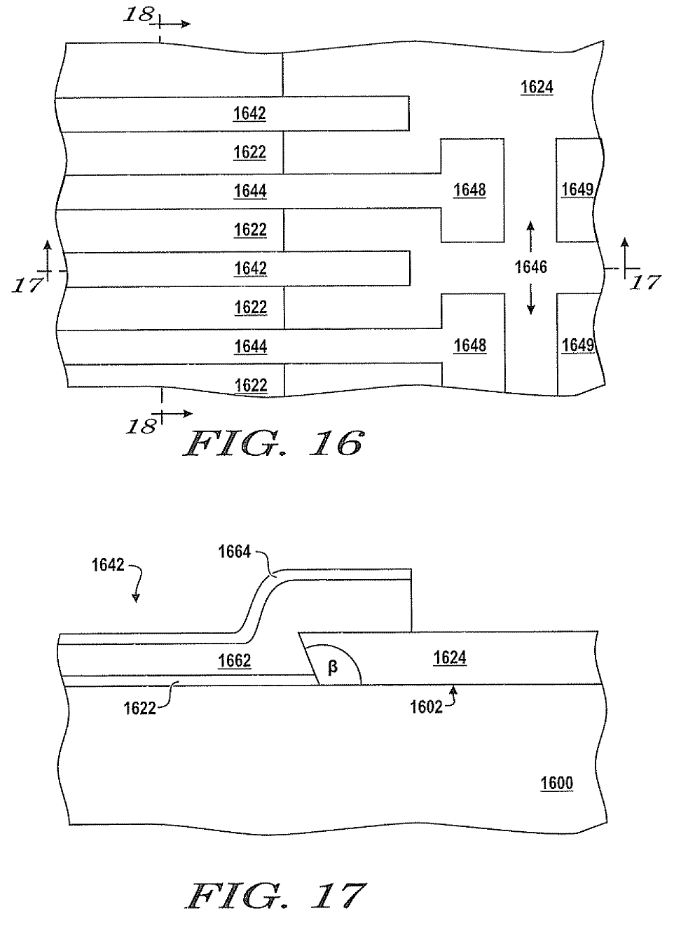

FIGS. 16 to 19 include illustrations at a point in processing similar to the embodiment as described with respect to FIG. 9. Unlike the embodiment illustrated in FIG. 9, a feature has an overhanging portion that can make detection of a defect by optical methods nearly impossible.

Referring to FIGS. 16 and 17, a dielectric layer 1622 and a patterned insulating layer 1624 overlie a substrate 1600. Word lines 1642 and 1644 are similar to word lines 92 and 94. Word lines 1644 have been severed to define gaps 1646 between flared portions 1648 and 1649. Each of the word lines 1642 and 1644 include a conductive layer 1662 and a hard mask layer 1664. The dielectric layer 1622, the conductive layer 1662 and the hard mask layer 1664 can have any of the films, materials, thicknesses, and formation techniques as previously described with respect to the dielectric layer 52, the conductive layer 542, and the hard mask layer 544, respectively.

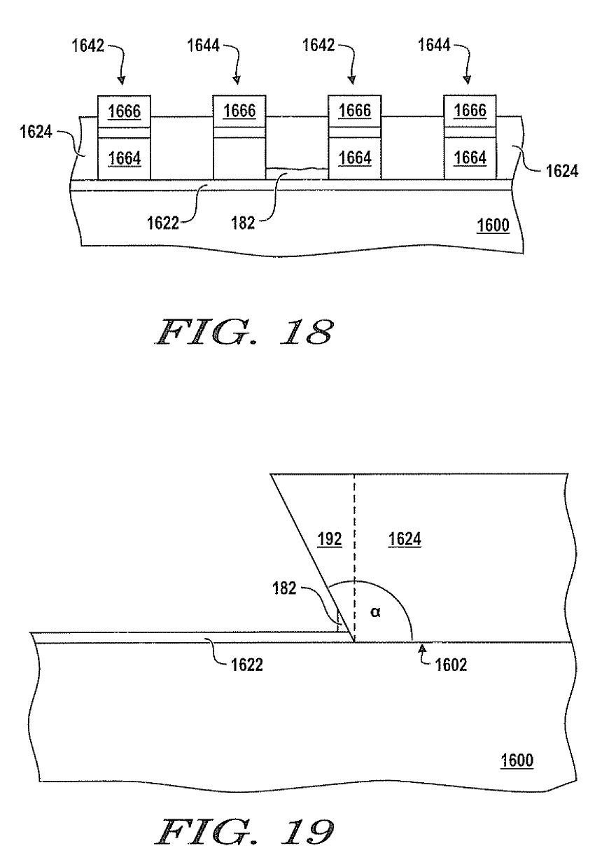

The patterned insulating layer 1624 can be an oxide, a nitride, an oxynitride, or any combination thereof. In an embodiment, the thickness of the patterned insulating layer 1624 can be at least half of the thickness of the conductive layer 1662, substantially the same thickness as the conductive layer 1662, or thicker than the conductive layer 1662. In a particular embodiment, the patterned insulating layer 1624 has a thickness in a range of approximately 20 nm to approximately 500 nm. In another particular embodiment, the patterned insulating layer 1624 has an edge that lies along an obtuse angle β with respect to the primary surface 1602 of the substrate 1600. The significance of the obtuse angle will be addressed with respect to FIGS. 18 and 19 below. The patterned insulating layer 1624 can be formed using a conventional or proprietary deposition and patterning technique.

Referring to FIGS. 18 and 19, the etching of the conductive layer 1662 can be performed as an anisotropic etch. A residual portion of the conductive layer 1662 may underlie an overhanging portion of the patterned insulating layer 1624 at the end of the etch. Such residual portion is undesired because it can act as a conduction path between adjacent word lines. FIG. 18 includes a cross-sectional view of the workpiece along sectioning line 18-18 in FIG. 16. More particularly, the overhanging portions 192 (as illustrated in FIG. 19) may cause part of conductive layer 1662 to be not completely etched, and leave an undesired residual portion 182 to lie between immediately adjacent word lines 1642 and 1644, as illustrated in FIG. 18. FIG. 19 includes an enlarged cross-sectional view between word lines 1642 and 1644. Thus, FIG. 19 is in a direction substantially perpendicular to the illustration in FIG. 18. FIG. 19 illustrates that the residual portion 182 of the conductive layer 1662 underlies the overhanging portion 192 of the patterned insulating layer 1624. The edge of the overhanging portion 192 (to the left of the dashed line in FIG. 19) lies along an obtuse angle β with respect to the primary surface 1602 of the substrate 1600. The residual portion 182 may not be detected by an optical microscope inspection because it is covered by the overhanging portion 192.

The testing techniques as previously described can be used to detect the presence of the residual portion 182. In a particular embodiment a voltage contrast inspect operation can be performed to electrically test and determine and that the word lines 1642 and 1644 as illustrated near the center of FIGS. 16 and 18 are electrically shorted. The word line 1644 as illustrated near the center of FIGS. 16 and 18 will illuminate, indicating that the particular word line 1644 is electrically shorted. Note that the test indicates an electrical short even though the residual portion 182 is not visible from a top view (e.g., FIG. 16).

### Example 4

Example 4 demonstrates how the concepts as described herein can be used in flows that do not require severing conductive members. For example, an insulating layer may be patterned such that contacts are not formed in a portion where the electronic device is to be tested, although such contacts are originally designed for the product dice.

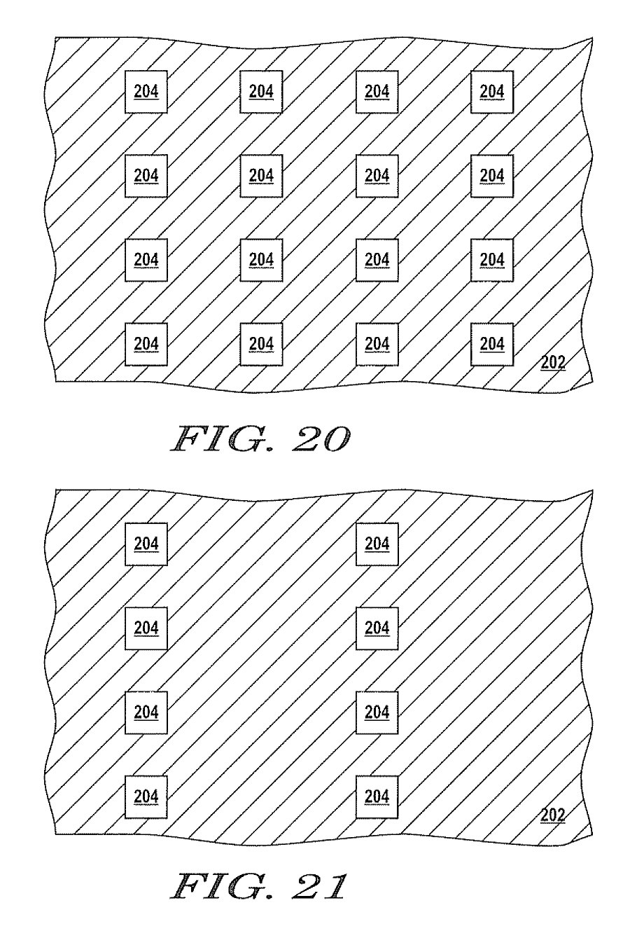

FIGS. 20 to 23 include illustrations of top views of workpieces, of which one workpiece will be tested and the other will not. Instead of severing a conductive members, no electrical contacts to underlying features will be formed for portions of electronic devices being tested. FIG. 20 includes a top view of a portion of workpiece that include product die that are not being tested. FIG. 20 includes a patterned insulating layer 202 and columns of contact openings 204. A conductive material is exposed at the bottom of the contact openings. Unlike the portion of the workpiece in FIG. 20, a portion of a workpiece as illustrated in FIG. 21 will be tested. Instead of forming four columns of contact openings 204 as illustrated in FIG. 20, only two columns of contact openings 204 are formed. Before patterning the insulating layer 202, the workpieces may have been substantially identical. A mask used to pattern the insulating layer 202 can be different for the different workpieces in FIGS. 20 and 21. The formation of the insulating layer 202 and patterning to form the contact openings 204 can be performed using conventional or proprietary techniques.

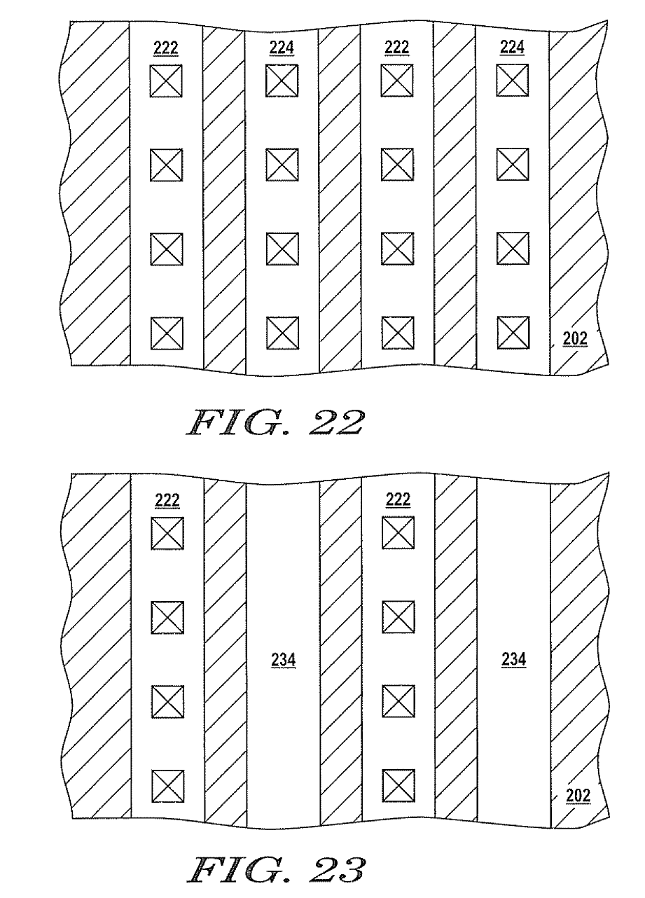

Conductive members 222, 224, and 234 can be formed as illustrated in FIGS. 22 and 23. The conductive members 222 and 224 can be interconnects, and more particularly bit lines in this embodiment, that make electrical contact to underlying conductive features (e.g., source/drain regions of transistors) through the contact openings, which are illustrated as [symbol] symbols. In this particular embodiment, the conductive members 234 do not overlie contact openings, and therefore, the conductive members 234 are to electrically float in the absence of a defect. The testing techniques as previously described can be used to detect the presence of a defect between the conductive members 222 and 234. In a particular embodiment, a voltage contact inspect operation can be performed. If no defect is present, the conductive members 234 will be illuminated, and if a defect forms a conductive path between a particular conductive member 234 and an immediately adjacent conductive member 222, the particular conductive member 234 will be illuminated.

After reading this specification, skilled artisans will appreciate that the concepts as described in these Examples can be extended to situations. For example, even if functional die are being produced, an implant dose may be tested to determine if increasing or decreasing the dose reduces a read access time that may allow the product die to be sold for a higher price. The process can be used for metal bit lines that are formed by etching a metal containing material. The conductors can be part of other memory cells (static random access memory cells, dynamic random access memory cells, magnetoresistive random access memory cells, or the like) in addition to or in place of the nonvolatile memory cells. The process can also be used in logic applications, such as microprocessors, microcontrollers, digital signal processors, or product die with specialized cores (e.g., engine controllers, focus control circuits within digital cameras, etc.). After reading the specification, skilled artisans will appreciate that the process can be adapted for use in making a variety of different product dice.

Embodiments as described herein can allow for ad-hoc tests to be performed where the sample size can be quickly changed. The process can provide quicker and more accurate detection of defects, determination process margins, discovery of potential performance improvements, other suitable information regarding process integration issues, or any combination thereof. The workpieces do not need to be processed through the entire fabrication process flow only to have conduction paths detected at a sort operation. The test is performed as an electrical test, and thus, can detect defects that are otherwise not visible using an optical microscope and can be used to analyze a larger area more quickly than a SEM analysis. Because the problem is detected much earlier, a remedial action on the workpiece can be performed, adjustments to the processing of subsequent workpieces within the same lot can be made before completing a current process step, or other lots, which would otherwise be processed before the current lot is at sort, can be processed differently, or the like. Further, the test can be correlated with other processing or environmental conditions. For example, a higher number of conduction paths may correlate to high particle counts within a processing chamber.

The processing and test can be useful in determining how small of a pitch can be used for process integration issues. For example, without changing the thicknesses of any layers, the processing and test as described herein can be used to determine that a pitch for word lines may be reduced by 20% before the number of conduction paths between word lines become unacceptably high.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a process of fabricating a workpiece can include forming a first feature over a substrate, and forming a patterned mask layer over the substrate, wherein the patterned mask layer corresponds at least in part to a test mask. The process can also include performing a process operation while the patterned mask layer overlies the substrate to alter the first feature to form a second feature, and performing an electrical test after performing the process operation. The process can further include forming a bond pad of a product die over the substrate for a first time after performing the electrical test.

In an embodiment of the first aspect, the first feature is part of a first product die, and wherein the second feature does not correspond to a designed feature of the first product die. In a particular embodiment, the process further includes forming a third feature that is part of a second product die, wherein the third feature and the second product die are substantially identical to the first feature and the first product die, respectively, and forming bond pads for the second product die after forming the third feature, wherein the third feature is not formed using the patterned mask layer and is substantially unchanged after forming the third feature.

In a more particular embodiment of the first aspect, the first product die and the second product die are part of the same product lot. In an even more particular embodiment, the first product die and the second product die are different parts of the substrate. In another more particular embodiment, the process further includes forming a fourth feature that is part of a third product die, wherein the fourth feature and the third product die are substantially identical to the first feature and the first product die, respectively, and forming the patterned mask layer over the third product die. The process also includes performing the process operation while the patterned mask layer overlies the substrate to alter the fourth feature to form a fifth feature, and performing the electrical test that uses the fifth feature. The process further includes forming bond pads for the third product die after performing the electrical test. The first product die is part of a first product lot, the second product die is part of a second product lot different from and formed after the first product lot, and the third product die is part of a third product lot different from and formed after the first and second product lots.

In another embodiment of the first aspect, the electrical test is performed without a test pad or a bond pad over the substrate. In still another embodiment, the electrical test includes a voltage contrast inspection.

In a second aspect, a process of fabricating a workpiece can include forming a first conductive member and a second conductive member over a substrate of a product die, wherein the first and second conductive members are spaced apart from each other and are designed to be electrically isolated from each other. The process can also include exposing the first and second conductive members to a charged ambient, and determining whether a conduction path exists between the first and second conductive members based on exposing the first and second conductive members to a charged ambient.

In an embodiment of the second aspect, the process further includes forming a patterned insulating layer over the substrate before forming the first and second conductive members, wherein the patterned insulating layer includes an overhanging portion and an edge that lies along an obtuse angle with respect to a primary surface of the substrate. In a particular embodiment, forming the first and second conductive members comprises forming a residual portion of a conductive layer underlying the overhanging portion of the insulating layer, wherein the residual portion is part of the conduction path between the first and second conductive members. In a more particular embodiment, forming the first and second conductive members comprises forming the conductive layer over the substrate and patterned insulating layer, wherein part of the conductive layer underlies the overhanging portion, and anisotropically etching the conductive layer to define the first and second conductive members.

In another embodiment of the second aspect, exposing the first and second conductive members to a charged ambient and determining whether the conduction path exists between the first and second conductive members are parts of a voltage contrast inspection. In a particular embodiment, forming the first and second conductive members includes forming a first set of word lines and a second set of word lines for a memory sector, the first set of word lines includes the first conductive member, and the first set of word lines extends further outside the memory sector along one side of the memory sector, as compared to the second set of word lines, and the second set of word lines includes the second conductive member, and the second set of word lines extends further outside the memory sector along a different side of the memory sector, as compared to the first set of word lines. In another particular embodiment, forming the first conductive member and the second conductive member changes the product die to a converted test die, and the process further includes forming bond pads within the converted test die.

In still another embodiment, the workpiece includes a first product die and a second product die, and the process further includes forming a conductive layer over the substrate and within the first and second product die. After forming the conductive layer and before forming the first and second conductive members, the first product die is substantially identical to the second product die. Forming the first and second conductive members includes forming a third conductive member and a fourth conductive member, wherein the first and second conductive members are parts of the first product die, and the third and fourth conductive members are parts of the second product die. The third conductive member includes a portion of the conductive layer and is substantially identical to the first conductive member, and the fourth conductive member includes another portion of the conductive layers and is significantly different from the second conductive member.

In a further embodiment, forming the first and second conductive members further includes forming a mask marker for a particular die. The process further includes forming a bond pad over the substrate after exposing the first and second conductive members to the charged ambient, detecting the mask marker, and bypassing a wafer sort operation for the particular die in response to detecting the mask marker.

In a third aspect, a process of fabricating a workpiece can include forming an insulating layer over a substrate of a product die, wherein the insulating layer overlies conductive features that are originally designed to be contacted by a subsequently formed conductive members. The process can also include patterning the insulating layer such that openings are not formed to a particular conductive features that is originally designed to be contacted by a subsequently formed particular conductive member. The process can further include forming conductive members including the particular conductive member and an adjacent conductive member, wherein the particular conductive member overlies the conductive feature to which the particular conductive member is originally designed to contact. The process can still further include determining whether a conduction path exists between the particular and adjacent conductive members based on exposing the particular and adjacent conductive members to a charged ambient.

In an embodiment of the third aspect, determining whether a conduction path exists includes performing a voltage contrast inspection to determine whether a conduction path exists between two adjacent bit lines. In another embodiment, patterning the insulating layer also defines a mask marker in a particular die that designates the particular die is not be tested at a wafer sort.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of the invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. A process of fabricating a workpiece comprising:
forming a first feature over a substrate;
forming a patterned mask layer over the substrate, wherein the patterned mask layer corresponds at least in part to a test mask;
performing a process operation while the patterned mask layer overlies the substrate to alter the first feature to form a second feature;
performing an electrical test after performing the process operation; and
forming a bond pad of a product die over the substrate for a first time after performing the electrical test.

2. The process of claim 1, wherein the first feature is part of a first product die, and wherein the second feature does not correspond to a designed feature of the first product die.

3. The process of claim 2, further comprising:
forming a third feature that is part of a second product die, wherein the third feature and the second product die are substantially identical to the first feature and the first product die, respectively; and
forming bond pads for the second product die after forming the third feature, wherein the third feature is not formed using the patterned mask layer and is substantially unchanged after forming the third feature.

4. The process of claim 3, wherein the first product die and the second product die are part of a same product lot.

5. The process of claim 4, wherein the first product die and the second product die are different parts of the substrate.

6. The process of claim 3, further comprising:
forming a fourth feature that is part of a third product die, wherein the fourth feature and the third product die are substantially identical to the first feature and the first product die, respectively;
forming the patterned mask layer over the third product die;
performing the process operation while the patterned mask layer overlies the substrate to alter the fourth feature to form a fifth feature;
performing the electrical test that uses the fifth feature; and
forming bond pads for the third product die after performing the electrical test,
wherein:
the first product die is part of a first product lot;
the second product die is part of a second product lot different from and formed after the first product lot; and
the third product die is part of a third product lot different from and formed after the first and second product lots.

7. The process of claim 1, wherein the electrical test is performed without a test pad or a bond pad over the substrate.

8. The process of claim 1, wherein the electrical test comprises a voltage contrast inspection.

9. A process of fabricating a workpiece comprising:
forming a first conductive member and a second conductive member over a substrate of a product die, wherein the first and second conductive members are spaced apart from each other and are designed to be electrically isolated from each other;
exposing the first and second conductive members to a charged ambient; and
determining whether a conduction path exists between the first and second conductive members based on exposing the first and second conductive members to a charged ambient.

10. The process of claim 9, further comprising forming a patterned insulating layer over the substrate before forming the first and second conductive members, wherein the patterned insulating layer includes an overhanging portion and an edge that lies along an obtuse angle with respect to a primary surface of the substrate.

11. The process of claim 10, wherein forming the first and second conductive members comprises forming a residual portion of a conductive layer underlying the overhanging portion of the insulating layer, wherein the residual portion is part of the conduction path between the first and second conductive members.

12. The process of claim 11, wherein forming the first and second conductive members comprises:
forming the conductive layer over the substrate and patterned insulating layer, wherein part of the conductive layer underlies the overhanging portion; and
anisotropically etching the conductive layer to define the first and second conductive members.

13. The process of claim 9, wherein exposing the first and second conductive members to a charged ambient and determining whether the conduction path exists between the first and second conductive members are parts of a voltage contrast inspection.

14. The process of claim 13, wherein:
forming the first and second conductive members comprises forming a first set of word lines and a second set of word lines for a memory sector;
the first set of word lines includes the first conductive member, and the first set of word lines extends further outside the memory sector along one side of the memory sector, as compared to the second set of word lines; and
the second set of word lines includes the second conductive member, and the second set of word lines extends further outside the memory sector along a different side of the memory sector, as compared to the first set of word lines.

15. The process of claim 13, wherein:
forming the first conductive member and the second conductive member changes the product die to a converted test die; and
the process further comprises forming bond pads within the converted test die.

16. The process of claim 9, wherein:
the workpiece comprises a first product die and a second product die;
the process further includes forming a conductive layer over the substrate and within the first and second product die;
after forming the conductive layer and before forming the first and second conductive members, the first product die is substantially identical to the second product die;
forming the first and second conductive members comprises forming a third conductive member and a fourth conductive member, wherein the first and second conductive members are parts of the first product die, and the third and fourth conductive members are parts of the second product die;
the third conductive member includes a portion of the conductive layer and is substantially identical to the first conductive member;
the fourth conductive member includes another portion of the conductive layers and is significantly different from the second conductive member.

17. The process of claim 9, wherein:
forming the first and second conductive members further comprises forming a mask marker for a particular die; and
the process further comprises:
forming a bond pad over the substrate after exposing the first and second conductive members to the charged ambient;
detecting the mask marker; and
bypassing a wafer sort operation for the particular die in response to detecting the mask marker.

18. A process of fabricating a workpiece comprising:
forming an insulating layer over a substrate of a product die, wherein the insulating layer overlies conductive features that are originally designed to be contacted by a subsequently formed conductive members;
patterning the insulating layer such that openings are not formed to a particular conductive features that is originally designed to be contacted by a subsequently formed particular conductive member;
forming conductive members including the particular conductive member and an adjacent conductive member, wherein the particular conductive member overlies the conductive feature to which the particular conductive member is originally designed to contact; and
determining whether a conduction path exists between the particular and adjacent conductive members based on exposing the particular and adjacent conductive members to a charged ambient.

19. The process of claim 18, wherein determining whether a conduction path exists comprises performing a voltage contrast inspection to determine whether a conduction path exists between two adjacent bit lines.

20. The process of claim 18, wherein patterning the insulating layer also defines a mask marker in a particular die that designates the product die is not be tested at a wafer sort.
